(19) United States
(12) Patent Application Publication
(10) Pub. No.: US 2014/0252605 A1
(43) Pub. Date: Sep. 11, 2014

(54) SEMICONDUCTOR PACKAGE AND METHOD OF FABRICATING THE SAME

(71) Applicant: Samsung Electronics Co., Ltd., Suwon-si (KR)

(72) Inventors: Keum-Hee MA, Suwon-si (KR); Cha-Jea JO, Bucheon-si (KR); Sang-Uk HAN, Hwaseong-si (KR)

(73) Assignee: Samsung Electronics Co., Ltd., Suwon-si (KR)

(21) Appl. No.: 14/198,713

(22) Filed: Mar. 6, 2014

(30) Foreign Application Priority Data
Mar. 7, 2013 (KR) 10-2013-0024496

(51) Int. Cl. H01L 25/00; H01L 25/065

(52) U.S. Cl. CPC H01L 25/50; H01L 25/0657
USPC 257/737; 438/109

(57) ABSTRACT

Provided are a semiconductor package and a method of fabricating the same. The method of fabricating the semiconductor package includes arranging each of a plurality of second semiconductor chips and each of a plurality of first semiconductor chips to be electrically connected to each other on a first wafer which includes the plurality of first semiconductor chips, with a first width of each of the first semiconductor chips is greater than a second width of each of the second semiconductor chips, forming a first molding layer surrounding the second semiconductor chips on the first wafer, forming a chip package including the first and second semiconductor chips by sawing the first wafer in units of the first semiconductor chips, arranging the chip package on a package substrate to electrically connect the second semiconductor chips to the package substrate, and forming a second molding layer surrounding the chip package on the package substrate.

### CROSS-REFERENCE TO RELATED APPLICATIONS

This application claims priority under 35 U.S.C. §119(a) from Korean Patent Application No. 10-2013-0024496 filed on Mar. 7, 2013 in the Korean Intellectual Property Office, and all the benefits accruing therefrom under 35 U.S.C. §119, the contents of which in its entirety are herein incorporated by reference.

### BACKGROUND OF THE INVENTION

1. Field of the Invention

The present general inventive concept relates to a semiconductor package and method for fabricating the same.

2. Description of the Related Art

One of primary concerns in the semiconductor industry is to fabricate small-sized, multi-functional, high-capacity, high-reliability semiconductor products at low costs. Semiconductor packaging is one of important technologies for achieving such complicated goals. To achieve the complicated goals, among various semiconductor packaging technologies, a stacked semiconductor packaging process in which a plurality of chips are stacked is being proposed.

There are various approaches for stacking semiconductor packages, including a chip on chip (CoC) process, a chip on wafer (CoW) process, and so on. In the CoW process, a semiconductor package is disposed on a wafer and then singulated by sawing, thereby manufacturing the semiconductor at a time, which is advantageous in view of process simplification and cost reduction.

### SUMMARY OF THE INVENTION

The present general inventive concept provides a method of fabricating a semiconductor package, which can reduce the fabrication cost using a CoW process and has an improved process speed.

The present general inventive concept also provides a semiconductor package, which can reduce the fabrication cost using a CoW process and has an improved process speed.

Additional features and utilities of the present general inventive concept will be set forth in part in the description which follows and, in part, will be obvious from the description, or may be learned by practice of the general inventive concept.

Exemplary embodiments of the present general inventive concept provide a method of fabricating a semiconductor package, the method including arranging a plurality of first semiconductor chips, each having a first width, and a plurality of second semiconductor chips, each having a second width, to be electrically connected to each other on a first wafer which includes the plurality of first semiconductor chips, where the first width of each of the first semiconductor chips being greater than the second width of each of the second semiconductor chips, forming a first molding layer surrounding the second semiconductor chips on the first wafer, forming a chip package including the first and second semiconductor chips by sawing the first wafer in units of the first semiconductor chips, arranging the chip package on a package substrate to electrically connect the second semiconductor chips to the package substrate, and forming a second molding layer surrounding the chip package on the package substrate.

Exemplary embodiments of the present general inventive concept may also provide a semiconductor package including a package substrate, a first semiconductor chip having a first width, and a second semiconductor chip having a second width formed on the package substrate and including through silicon vias (TSVs), with the first semiconductor chip being disposed on the second semiconductor chip and the first width of the first semiconductor chip being greater than the second width of the second semiconductor chip, a first molding layer surrounding the second semiconductor chip and formed under the first semiconductor chip without being formed on lateral surfaces of the first semiconductor chip, the first molding layer having a width that is smaller than or equal to the first width of the first semiconductor chip, and a second molding layer formed on the package substrate and surrounding the first molding layer and the first semiconductor chip.

Exemplary embodiments of the present general inventive concept may also provide a method of fabricating a semiconductor device, the method including sequentially stacking a plurality of first semiconductor chips, each having a first width, onto a plurality of second semiconductor chips, each having a second width, onto a wafer, the plurality of first semiconductor chips being disposed on the plurality of second semiconductor chips, respectively, the first width of each of the first semiconductor chips being greater than the second width of each of the second semiconductor chips, forming a first molding layer surrounding the second semiconductor chips, sawing the wafer into chip packages, with each of the chip packages including the first and second semiconductor chips, arranging each of the chip packages on respective package substrates to electrically connect the second semiconductor chips to the package substrates, and forming a second molding layer surrounding each of the chip packages on the respective package substrates.

Exemplary embodiments of the present general inventive concept may also provide a method of fabricating a semiconductor device, the method including forming, on a package substrate, a first semiconductor chip having a first width, a second semiconductor chip having a second width and including through silicon vias (TSVs), with the second semiconductor chip being formed on the package substrate and the first semiconductor chip being disposed on the second semiconductor chip, with the first width of the first semiconductor chip being greater than the second width of the second semiconductor chip, forming a first molding layer to surround the second semiconductor chip, including an area between the first semiconductor chip and the second semiconductor chip, the first molding layer having a width that is smaller than or equal to the first width of the first semiconductor chip, and forming a second molding layer on the package substrate and surrounding the first molding layer and the first semiconductor chip.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view of a semiconductor package according to an exemplary embodiment of the present general inventive concept;

FIG. 2 is a flowchart of a method of fabricating a semiconductor package according to an embodiment of the present general inventive concept;

FIGS. 3 to 11 illustrate intermediate process steps in a method of fabricating a semiconductor package according to an embodiment of the present general inventive concept;

FIG. 12 is a flowchart illustrating a method of fabricating second semiconductor chips according to an exemplary embodiment of the present general inventive concept;

FIGS. 13 to 17 illustrate an intermediate process in the method of fabricating second semiconductor chips illustrated in FIG. 12;

FIG. 18 is a schematic view illustrating a memory card to which semiconductor packages according to exemplary embodiments of the present general inventive concept are employed;

FIG. 19 is a block diagram of an electronic system to which a semiconductor package according to exemplary embodiments of the present general inventive concept is employed; and

FIG. 20 illustrates an exemplary electronic system included in a smart phone.

### DETAILED DESCRIPTION OF THE PREFERRED EMBODIMENTS

The present inventive concept will now be described more fully hereinafter with reference to the accompanying drawings, in which preferred embodiments of the general inventive concept are illustrated. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

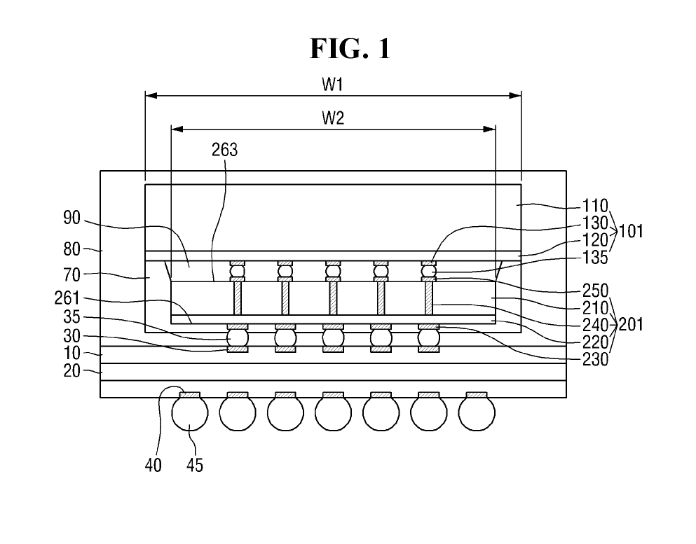

Hereinafter, a semiconductor package according to an embodiment of the present general inventive concept will be described with reference to FIG. 1.

FIG. 1 is a cross-sectional view of a semiconductor package according to an exemplary embodiment of the present general inventive concept.

Referring to FIG. 1, the semiconductor package includes a package substrate 10, a first semiconductor chip 101, a second semiconductor chip 201, a first molding layer 70 and a second molding layer 80.

A package substrate 10 may have a printed circuit 20 having a predetermined shape on a substrate made of, for example, glass, ceramic, or plastic, but the present general inventive concept is not limited thereto. An external terminal 45 electrically connecting a semiconductor package to an external device (not illustrated) may be formed on a bottom surface of the package substrate 10. The external terminal 45 may be formed in a grid array, such as a pin grid array, a ball grid array, or a land grid array. Package bottom pads 40 may be electrically connected to the external terminal 45 connected to the external device, and the package bottom pads may be electrically connected to the printed circuit 20 of the package substrate 10. The package substrate 10 may supply electrical signals to the first semiconductor chip 101 and the second semiconductor chip 201 through fourth pads 30 formed on a top surface of the package substrate 10. At least one of the package bottom pads 40 may be, for example, a ground pad, and may be electrically connected to a ground line in the package substrate 10. In FIG. 1, the package bottom pads 40 are arranged at the center of the package substrate 10, but the present general inventive concept is not limited thereto.

The second semiconductor chip 201 and the first semiconductor chip 101 may be sequentially stacked on the package substrate 10. In detail, the second semiconductor chip 201 may be arranged on the package substrate 10, and the first semiconductor chip 101 may be arranged on the second semiconductor 201. The second semiconductor chip 201 and the first semiconductor chip 101 may be, for example, flip chips.

The second semiconductor chip 201 and the first semiconductor chip 101 may be, for example, memory chips or logic chips. When the second semiconductor chip 201 and/or the first semiconductor chip 101 are logic chips, they may be designed in various manners in consideration of operations executed. Here, the logic chip may be a microprocessor, for example, a central processing unit (CPU), a controller, or an application specific integrated circuit (ASIC). When the second semiconductor chip 201 and/or first semiconductor chip 101 are memory chips, the memory chips may be, for example, volatile memories such as DRAMs or SRAMs, or nonvolatile memories such as flash memories. In detail, the memory chip may be a flash memory chip. In more detail, the memory chip may be either a NAND flash memory chip or a NOR flash memory chip. However, the present general inventive concept does not limit the type of the memory chip to those listed therein. In exemplary embodiments of the present general inventive concept, the memory chip may include one of a phase change random access memory (PRAM)), a magneto-resistive random access memory (MRAM), and a resistive random access memory (RRAM).

The second semiconductor chip 201 is arranged on the package substrate 10. The second semiconductor chip 201 includes a wafer 210, through silicon vias (TSVs) 240, a redistribution layer 220, first pads 250, and second pads 230.

The wafer 210 may be made of a semiconductor material or an insulating material. That is, in some embodiments of the present general inventive concept, the wafer 210 may include, for example, silicon (Si), germanium (Ge), silicon-germanium (SiGe), gallium arsenide (GaAs), glass, ceramic, and so on.

The TSVs 240 pass through the wafer 210. Each of the TSVs 240 may be configured such that an insulating layer, a seed layer and a conductive layer are sequentially stacked. The insulating layer may electrically insulate the conductive layer.

The insulating layer may include oxide, nitride or oxynitride. In detail, the insulating layer may include, for example, silicon oxide, silicon nitride or silicon oxynitride. The conductive layer may include a conductive material, for example, a metal. Examples of the metal forming the TSVs 240 may include, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellium (Te), titanium (Ti), tungsten (W), zinc (Zn), zirconium (Zr), and so on, but aspects of the present general inventive concept are not limited thereto.

The insulating layer, the seed layer and the conductive layer, forming the TSVs 240, may be formed by chemical vapor deposition (CVD), plasma enhanced chemical vapor deposition (PECVD), high density plasma chemical vapor deposition (HDP-CVD), sputtering, metal organic chemical vapor deposition (MOCVD), or atomic layer deposition (ALD), but aspects of the present general inventive concept are not limited thereto.

The TSVs 240 may be directly connected to the first pads 250 formed on a first surface 263, and the first pads 250 may be electrically connected to third pads 130 of the first semiconductor chip 101. The first semiconductor chip 101 and the second semiconductor chip 201 may be electrically connected to each other through the TSVs 240.

The redistribution layer 220 may be electrically connected to the second pads 230 formed on a second surface 261. The second pads 230 may be electrically connected to the TSVs 240 through a redistribution line formed in the redistribution layer 220. In FIG. 1, the first pads 250, the second pads 230 and the TSVs 240 are formed on a straight line, but the present general inventive concept is not limited thereto. The second pads 230 and the TSVs 240 may not be formed on a straight line.

The redistribution layer 220 may further include an insulating layer to electrically insulate the redistribution lines provided therein. The insulating layer may include oxide, nitride or oxynitride. In detail, the insulating layer may include, for example, silicon oxide, silicon nitride or silicon oxynitride.

The redistribution line in the redistribution layer 220 may include, for example, a metal. In an exemplary embodiment of the present general inventive concept, the redistribution line in the redistribution layer 220 may be made of the same material as that of the TSV 240, but aspects of the present general inventive concept are not limited thereto.

The second semiconductor chip 201 may be electrically connected to the package substrate 10 through the second pads 230 formed on the second surface 261. In detail, the second bumps 35 are arranged between the second pads 230 and the fourth pads 30, and electrically connect the second pads 230 to the fourth pads 30.

In an exemplary embodiment of the present general inventive concept, the second semiconductor chip 201 including the TSVs 240 is a single chip, which is provided only for brevity of explanation, but the present general inventive concept are not limited thereto.

The first semiconductor chip 101 may be electrically connected to the second semiconductor chip 201. The third pads 130 of the first semiconductor chip 101 are connected to the first pads 250 of the second semiconductor chip 201 through the first bumps 135, so that the first semiconductor chip 101 may be electrically connected to the second semiconductor chip 201. The first semiconductor chip 101 includes a wafer 110 and a semiconductor device circuit 120, and the third pads 130 may be formed on a surface of the first semiconductor chip 101 having the semiconductor device circuit 120 formed thereon.

The first semiconductor chip 101 may be electrically connected to the package substrate 10 through the TSVs 240 formed in the second semiconductor chip 201. In detail, the first semiconductor chip 101 may be electrically connected to the package substrate 10 through the third pads 130, the first pads 250, the TSVs 240, the second pads 230 and the fourth pads 30.

In an exemplary embodiment of the present general inventive concept, the first semiconductor chip 101 is a single chip, which is provided only for brevity of explanation, but the present general inventive concept is not limited thereto.

As illustrated in FIG. 1, an underfill layer 90 may be formed between the first semiconductor chip 101 and the second semiconductor chip 201. The underfill layer 90 may fill a space between the first semiconductor chip 101 and the second semiconductor chip 201 and may be formed in the first molding layer 70 while surrounding the first bumps 135. The underfill layer 90 protects the third pads 130 of the first semiconductor chip 101, protects the first pads 250 of the second semiconductor chip 201, and protects the first bumps 135 formed between the third pads 130 and the first pads 250 from external environments, thereby increasing the reliability in electrical connection between each of the third pads 130, the first bumps 135 and the first pads 250.

As illustrated in FIG. 1, a first width W1 of the first semiconductor chip 101 can be greater than a second width W2 of the second semiconductor chip 201. Therefore, the first semiconductor chip 101 is disposed on the second semiconductor chip 201 smaller in size than the semiconductor chip 101 itself.

The first molding layer 70 is formed between the first semiconductor chip 101 and the package substrate 10. The first molding layer 70 surrounds the second semiconductor chip 201. The second semiconductor chip 201 is not exposed to the outside by the first molding layer 70. The first molding layer 70 is formed under the first semiconductor chip 101 while not being formed on lateral surfaces of the first semiconductor chip 101, as illustrated. A width of the first molding layer 70 may be equal to or smaller than the first width W1 of the first semiconductor chip 101. That is, the width of the first molding layer 70 may not be greater than the first width W1 of the first semiconductor chip 101, which will later be described. The first molding layer 70 may be formed to protect the second semiconductor chip 201 from the outside in the course of fabricating the semiconductor package according to an embodiment of the present general inventive concept.

The second molding layer 80 is formed on the package substrate 10. In detail, the second molding layer 80 surrounds the first molding layer 70 and the first semiconductor chip 101 and fills a space between neighboring second bumps 35. Therefore, the first molding layer 70 and the first semiconductor chip 101 are not exposed to the outside by the second molding layer 80. The second molding layer 80 is provided for protecting the semiconductor package according to an embodiment of the present general inventive concept from the outside.

The first molding layer 70 and/or the second molding layer 80 may include, for example, an epoxy molding compound (EMC) or two or more types of silicon hybrid materials.

A method of fabricating a semiconductor package according to an embodiment of the present general inventive concept will be described with reference to FIGS. 1 and 2 to 11.

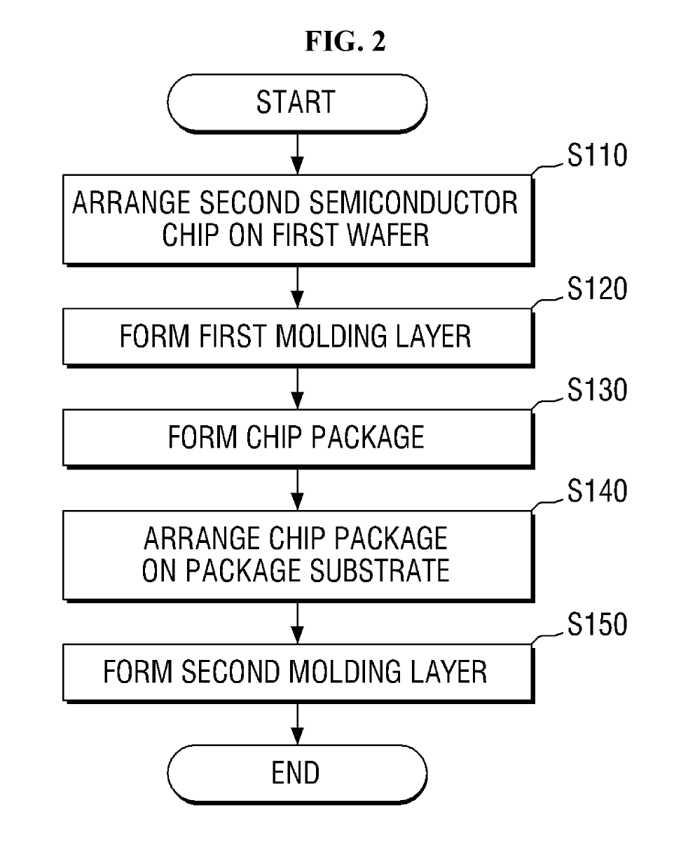

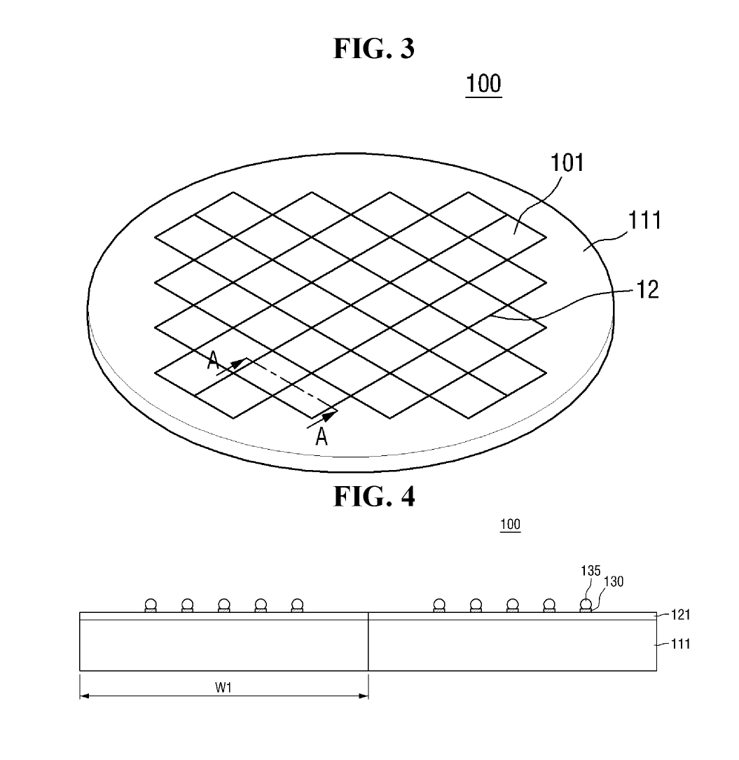

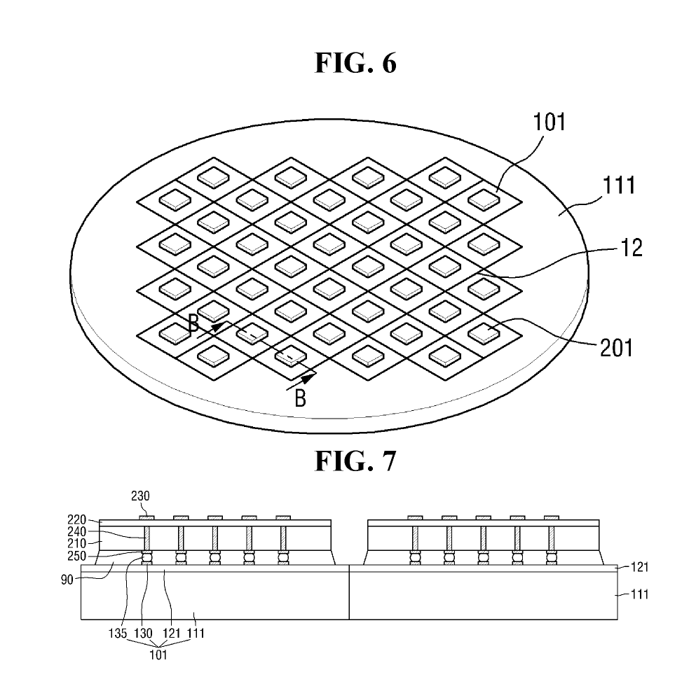

FIG. 2 is a flowchart of a method of fabricating a semiconductor package according to an embodiment of the present general inventive concept, and FIGS. 3 to 11 illustrate intermediate process steps in a method of fabricating a semiconductor package according to an embodiment of the present general inventive concept. Specifically, FIG. 4 is a cross-sectional view taken along the line A-A of FIG. 3, and FIGS. 7 to 11 are cross-sectional views taken along the line B-B of FIG. 6.

A first wafer 100 and a plurality of first semiconductor chips 101 are provided. Referring to FIGS. 3 and 4, the first wafer 100 includes the plurality of first semiconductor chips 101. The plurality of first semiconductor chips 101 may be separated from each other by scribing lines 12.

The first wafer 100 includes a wafer 111, a semiconductor device circuit 121 formed on a top surface of the wafer 111, and third pads 130 formed on the semiconductor device circuit 121. First bumps 135 are formed on top surfaces of the third pads 130. If the first wafer 100 is sawn along the scribing lines 12, each of the first semiconductor chips 101 may have a first width W1.

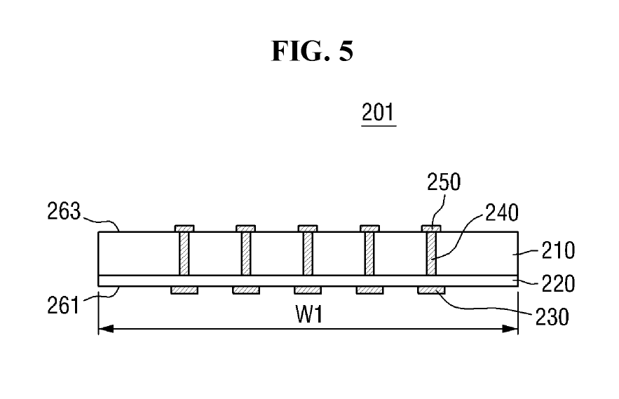

Referring to FIG. 5, a plurality of second semiconductor chips 201. However, only one of the plurality of second semiconductor chips 201 is illustrated in FIG. 5.

While the first semiconductor chips 101 are provided so as to be incorporated into the first wafer 100, the second semiconductor chip 201 is provided in form of a chip. The second semiconductor chip 201 has a second width W2 smaller than the first width W1 of each of the first semiconductor chips 101. The second semiconductor chip 201 includes a wafer 210, a redistribution layer 220, first pads 250 formed on a first surface 263, second pads 230 formed on the second surface 261, and a TSVs 240 passing through the wafer 210 and directly connected to the first pads 250, which has previously been described.

Referring to FIG. 2, at operation S110, the plurality of second semiconductor chips 201 are arranged on the first wafer 100 including the plurality of first semiconductor chips 101 to be electrically connected to the plurality of first semiconductor chips 101, respectively. Since the plurality of second semiconductor chips 201 are separated from each other, as illustrated in FIGS. 6 and 7, the second semiconductor chips 201 are arranged on the wafer 111 to be electrically connected to the first semiconductor chips 101. Here, the first pads 250 of each of the second semiconductor chips 201 are connected to the first bumps 135. The first pads 250 are electrically connected to the third pads 130 through the first bumps 135.

When the first semiconductor chips 101 and the second semiconductor chips 201 are electrically connected to each other through the first bumps 135, the underfill layer 90 may be formed between the first semiconductor chips 101 and the second semiconductor chips 201.

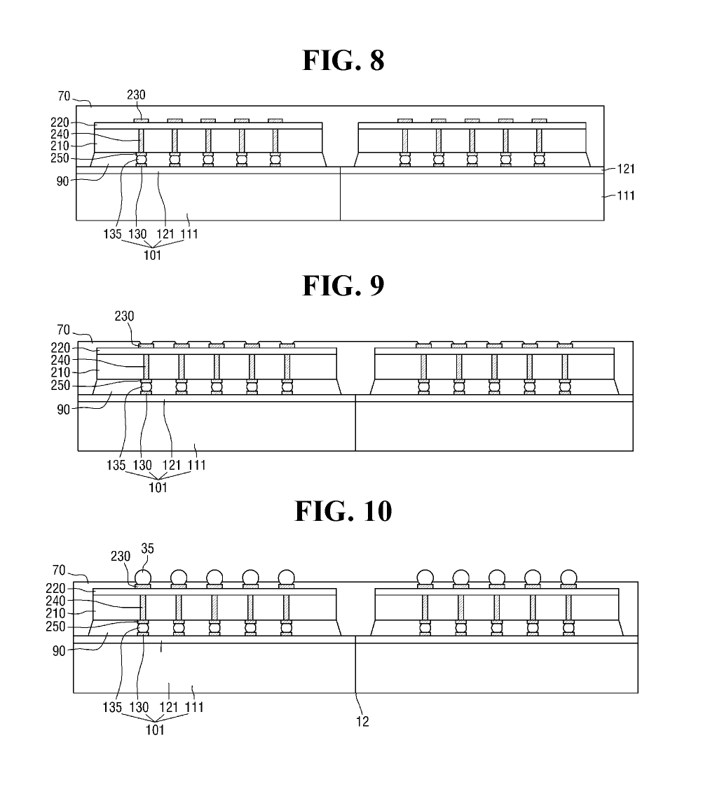

Referring again to FIG. 2, the first molding layer 70 surrounding the second semiconductor chips 201 is formed on the first wafer 100 at operation S120. Referring to FIG. 8, the first molding layer 70 covers the lateral surfaces and top surface of the first semiconductor chips 101 and the lateral surfaces of the underfill layer 90 on the first wafer 100. Therefore, the first semiconductor chips 101 and the underfill layer 90 are not exposed to the outside.

Referring to FIG. 9, the second pads 230 are exposed. The first molding layer 70 is patterned to expose the second pads 230. The patterning may be performed by, for example, a photolithography process or a laser etching process. Referring to FIG. 10, the second bumps 35 are formed on the exposed second pads 230.

Referring again to FIG. 2, at operation S130, a chip package including the first and second semiconductor chips 101 and 201, respectively, is formed by sawing the first wafer 100 in units of the first semiconductor chips 101. In FIG. 10, the first wafer 100 is sawn from the wafer 111 to the first molding layer 70 along the scribing lines 12. If the first wafer 100 is subjected to sawing along the scribing lines 12, the chip package, including the first semiconductor chips 101 and the second semiconductor chips 201, is formed. Since the first wafer 100 is subjected to sawing when the first molding layer 70 has been formed, the width of the first molding layer 70 may not be greater than that of the first semiconductor chips 101.

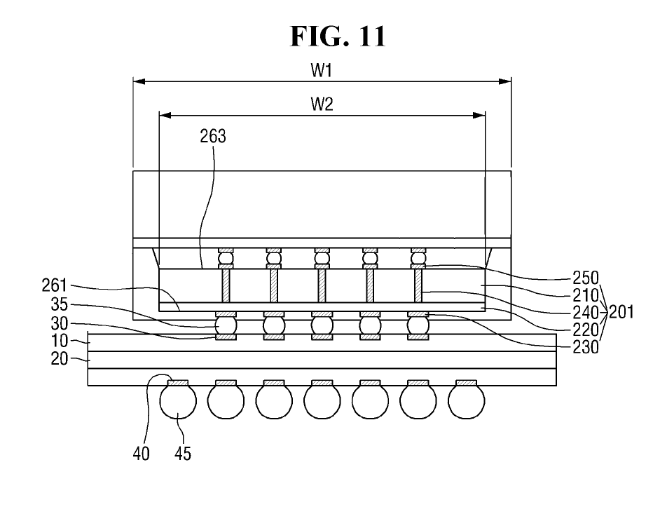

Referring again to FIG. 2, at operation S140, the chip package is disposed on the package substrate 10 to electrically the second semiconductor chips 201 to the package substrate 10. Referring to FIGS. 10 and 11, the second bumps 35 are connected to the fourth pads 30. That is, the chip package is electrically connected to the package substrate 10 through the second pads 230.

Consequently, in the semiconductor package according to an embodiment of the present general inventive concept, the second semiconductor chips 201 are smaller than the first semiconductor chips 101 in size. That is, the second semiconductor chips 201 each having the second width W2 smaller than the first width W1 of each of the first semiconductor chips 101, are arranged under the first semiconductor chips 101.

Referring again to FIG. 2, the second molding layer 80 surrounding the chip package is formed on the package substrate 10 at operation S150. Referring to FIG. 1, the second molding layer 80 completely cover the first semiconductor chips 101 and the first molding layer 70 so as not to be exposed to the outside. The second molding layer 80 may prevent the second bumps 35 from being exposed to the outside while surrounding the second bumps 35 between the second semiconductor chips 201 and the package substrate 10.

The package substrate 10 may be provided as a single substrate or may be provided as a wafer including a plurality of package substrates 10. In the latter case, a plurality of chip packages, that is, the first and second semiconductor chips 101 and 201 may be arranged on the package substrates 10 included in the wafer, and the wafer is sawn in a subsequent process, thereby forming the semiconductor package according to an embodiment of the present general inventive concept, including one package substrate 10, one first semiconductor chip 101 and one second semiconductor chip 201.

The semiconductor package according to the illustrated embodiment of the present general inventive concept includes two semiconductor chips, but the present general inventive concept is not limited thereto. The semiconductor package according to the embodiment of the present general inventive concept may include three or more semiconductor chips.

Hereinafter, a method of fabricating second semiconductor chips according to an embodiment of the present general inventive concept will be described with reference to FIGS. 5 and 12 to 17.

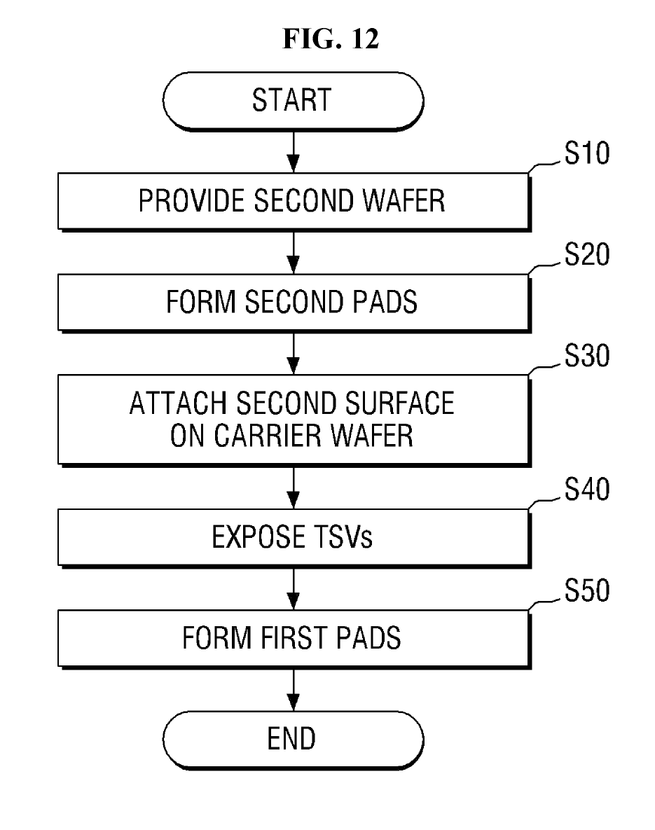

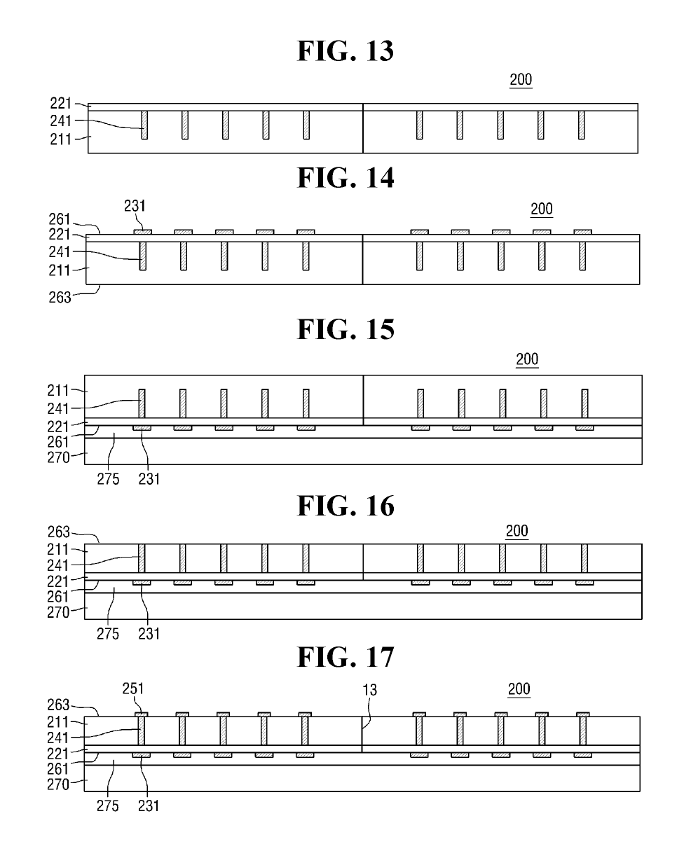

FIG. 12 is a flowchart illustrating a method of fabricating second semiconductor chips according to an embodiment of the present general inventive concept, and FIGS. 13 to 17 illustrate an intermediate process in the method of fabricating second semiconductor chips shown in FIG. 12.

Referring to FIG. 12, a second wafer 200 including a plurality of second semiconductor chips 201 is provided at operation S10. As illustrated in FIG. 13, the second wafer 200 includes a redistribution layer 221 and TSVs 241 formed in a wafer 211.

Referring again to FIG. 12, second pads 231 are formed on a second surface 261 of the second semiconductor chips 201 at operation S20. Referring to FIG. 14, the second surface 261 is a surface on which the redistribution layer 221 is formed.

When the second wafer 200 including the second semiconductor chips 201 is provided to be connected to the first semiconductor chips 101 on the second wafer 200, first bumps 135 are electrically connected to the first semiconductor chips 101 in a subsequent process. Therefore, in general, the second pads 231 are formed, and the first bumps 135 are formed on top surfaces of the second pads 231. However, in the present general inventive concept, since the first bumps 135 are formed before they are connected to the package substrate 10, they are not formed in the course of fabricating the second semiconductor chips 201.

Referring again to FIG. 12, the second surface 261 is attached to a carrier wafer 270 at operation S30. As illustrated in FIG. 15, in order to facilitate transportation of the second wafer 200 and to support the second wafer 200 in a subsequent process, the second surface 261 is attached to the carrier wafer 270. Here, in order to fix the second surface 261 on the carrier wafer 270, an adhesive layer 275 may be formed on the carrier wafer 270, and the second surface 261 may be adhered to the adhesive layer 275.

When the second surface 261 is adhered to the adhesive layer 275, the first bumps 135 formed on the second pads 231 may increase a thickness of the adhesive layer 275 due to heights of the first bumps 135, and there may be increased difficulty for the carrier wafer 270 to fix the second wafer 200 so as not to move. However, in the present general inventive concept, since the first bumps 135 are not formed in the course of fabricating the second semiconductor chips 201, there may be an increased ease in fixing the second wafer 200 to the carrier wafer 270 so as not to move.

Referring again to FIG. 12, the TSVs 241 are exposed at operation S40. Referring to FIG. 16, the wafer 211 is removed until the TSVs 241 are exposed to the outside. The TSVs 241 are configured to pass through the wafer 211.

In order to form the second semiconductor chips 201 to a desired thickness, a portion of the wafer 211 may be additionally cut. That is, the TSVs 241 may be exposed while thinning the plurality of second semiconductor chips 201. If the second semiconductor chips 201 are thinned, some portions of the TSVs 241 may also be removed.

Referring again to FIG. 12, first pads 251 directly connected to the TSVs 241 are formed on the first surface 263 of the second semiconductor chips 201 at operation S50. Referring to FIG. 17, after the wafer 211 is removed, the first pads 251 are formed on the first surface 263 having the TSVs 241 exposed to the outside. The first pads 251 are formed on top surfaces of the exposed TSVs 241 to be directly connected to the TSVs 241.

The second wafer 200 is sawn along scribing lines 13 of the wafer 211. As the result of sawing, a plurality of second semiconductor chips 201 may be separated from the second wafer 200, and each of the second semiconductor chips 201 may have such a shape as illustrated in FIG. 5. The thus formed second semiconductor chips 201 are electrically connected to the first semiconductor chips 101 on the first wafer 100.

In a general CoW process, the second semiconductor chips 201 are not provided in separate forms but are separated by sawing after they are connected to the first semiconductor chips 101 on the second wafer 200. However, in a case where the second semiconductor chips 201 are smaller than the first semiconductor chips 101 in size, a problem may arise. If the first semiconductor chips 101 are connected to the second semiconductor chips 201 on the second wafer 200 including the plurality of second semiconductor chips 201, since the first semiconductor chips 101 are larger than the second semiconductor chips 201 in size, only some of the plurality of second semiconductor chips 101 included in the second wafer 200 may be connected to the first semiconductor chips 101. To solve this problem, it is necessary to perform a CoC process, instead of a CoW process. In the CoC process, however, after the first semiconductor chips 101 are separated from the first wafer 100 and the second semiconductor chips 201 are separated from the second wafer 200, the first semiconductor chips 101 are connected to the second semiconductor chips 201, requiring a considerable time and production cost, compared to the CoW process.

However, like in the method of fabricating the semiconductor package according to an embodiment of the present general inventive concept, if the second semiconductor chips 201 are connected to the first semiconductor chips 101 on the first wafer 100, all of the second semiconductor chips 201 formed on a single wafer can be connected to the first semiconductor chips 101 using the CoW process. Therefore, even if the second semiconductor chips 201 are smaller than the first semiconductor chips 101 disposed on the second semiconductor chips 201, the semiconductor package according to the embodiment of the present general inventive concept can be fabricated without incurring additional time and cost.

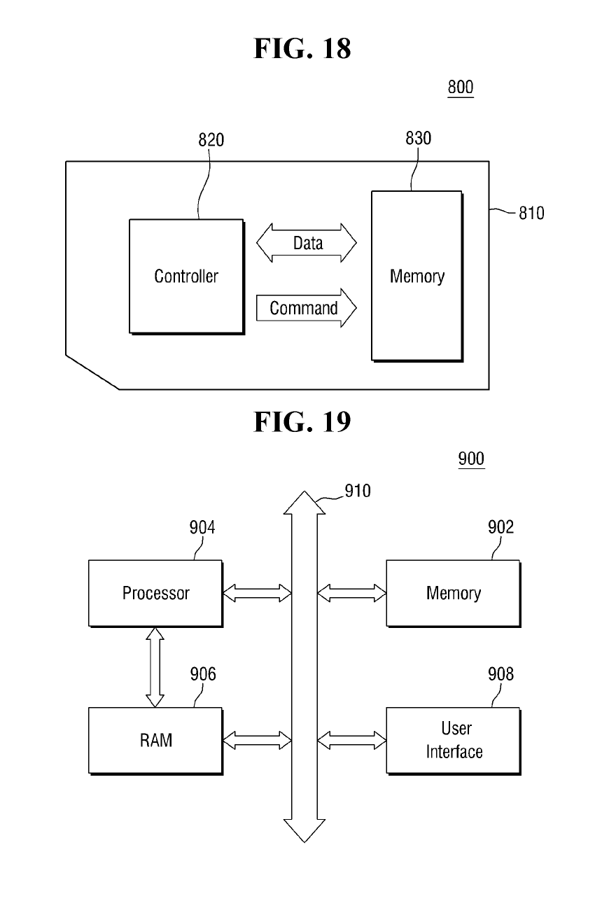

FIG. 18 is a schematic view illustrating a memory card to which semiconductor packages according to exemplary embodiments of the present general inventive concept are employed.

Referring to FIG. 18, a memory card 800 may include a memory controller 820 and a memory 830 in a housing 810. The controller 820 and the memory 830 may exchange electrical signals. For example, the controller 820 and the memory 830 may exchange data in response to a command of the controller 820. Accordingly, the memory card 800 may store data in the memory 830 or may output data from the memory 830 to the outside. That is, the memory card 800, when coupled to an external device, may store data that is generated by the external device, and/or may retrieve data stored in the memory 830 as requested by the external device.

The controller 820 or the memory 830 may include a semiconductor package according to an embodiment of the present general inventive concept. For example, the controller 820 may include a system in package (SIP) and the memory 830 may include a multi chip package (MCP). Meanwhile, the controller 820 and/or the memory 830 may be provided as a stack package (SP).

The memory card 800 may be used as a data storage medium for a variety of portable devices, such as a digital camera, a smart phone, a portable digital media player, a tablet computer, and/or any other suitable portable electronic device. For example, the memory card 800 may include a multi media card (MMC) or a secure digital (SD) card.

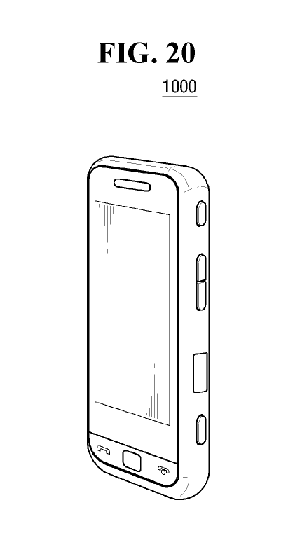

FIG. 19 is a block diagram of an electronic system to which a semiconductor package according to exemplary embodiments of the present general inventive concept is employed.

Referring to FIG. 19, the electronic system 900 may employ the semiconductor packages according to the above-described embodiments of the present general inventive concept. In detail, the electronic system 900 may include a memory system 902, a processor 904, a RAM 906, and a user interface 908.

The memory system 902, the processor 904, the RAM 906, and the user interface 918 may perform data communication with each other using a bus 910.

The processor 904 may execute a program and may control the electronic system 900, and the RAM 906 may be used as an operation memory of the processor 904. The processor 904 and the RAM 906 may be packaged as a single semiconductor device or a semiconductor package using the methods of fabricating the semiconductor packages according to the above-described embodiments of the present general inventive concept.

The user interface 908 may be used in inputting/outputting data to/from the electronic system 900. The memory system 902 may store codes for the operation of the processor 904, the data processed by the processor 904 or externally input data.

The memory system 902 may include a separate controller to drive the same, and may further include an error correction block. The error correction block may be configured to detect and correct an error of the data stored in the memory system 902 using an error correction code (ECC).

The memory system 902 can be integrated into one semiconductor device to constitute a memory card. For example, the memory system 902 can be integrated into one semiconductor device to form a memory card such as a personal computer memory card international association (PCMCIA) card, a compact flash (CF) card, a smart media card, a memory stick, a multimedia card (e.g., MMC, RS-MMC and MMC-micro), a secure digital (SD) card (e.g., SD, mini-SD, micro-SD and SDHC), or a universal flash storage (UFS) card.

The electronic system 900 illustrated in FIG. 19 can be applied to electronic controllers of various electronic devices.

FIG. 20 illustrates an exemplary electronic system (e.g., the electronic system 900 illustrated in FIG. 19) included in a smart phone. As illustrated in FIG. 20, in a case where the electronic system (e.g., electronic system 900 of FIG. 19) is included in a smart phone 1000, the electronic system (e.g., electronic system 900 of FIG. 19) may be, for example, an application processor (AP), but the present general inventive concept is not limited thereto.

In various embodiments, the memory system (e.g., electronic system 900 of FIG. 19) can be incorporated into a variety of different types of devices, such as computers, ultra mobile personal computers (UMPCs), work stations, net-books, personal digital assistants (PDAs), portable computers, web tablets, wireless phones, mobile phones, smart phones, e-books, portable multimedia players (PMPs), portable game consoles, navigation devices, black boxes, digital cameras, 3-dimensional televisions, digital audio recorders, digital audio players, digital video recorders, digital video players, devices capable of transmitting/receiving information in wireless environments, one of various electronic devices constituting a home network, one of various electronic devices constituting a computer network, one of various electronic devices constituting a telematics network, RFID devices, or computing systems.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A method of fabricating a semiconductor device, the method comprising:
arranging a plurality of first semiconductor chips, each having a first width, and a plurality of second semiconductor chips, each having a second width, to be electrically connected to each other on a first wafer which includes the plurality of first semiconductor chips, the first width of each of the first semiconductor chips being greater than the second width of each of the second semiconductor chips;
forming a first molding layer surrounding the second semiconductor chips on the first wafer;
forming a chip package including the first and second semiconductor chips by sawing the first wafer in units of the first semiconductor chips;
arranging the chip package on a package substrate to electrically connect the second semiconductor chips to the package substrate; and
forming a second molding layer surrounding the chip package on the package substrate.

2. The method of claim 1, wherein each of the second semiconductor chips include through silicon vias (TSVs).

3. The method of claim 2, wherein each of the second semiconductor chips includes first pads formed on a first surface and directly connected to the TSVs and second pads formed on a second surface, each of the first semiconductor chips including third pads, and the electrically connecting the first semiconductor chips to the second semiconductor chips comprises electrically connecting the first semiconductor chips to the second semiconductor chips through the first pads and the third pads.

4. The method of claim 3, after the forming the first molding layer, further comprising:
exposing the second pads by patterning the first molding layer; and
forming a bump on the second pad.

5. The method of claim 4, wherein the electrically connecting the chip package to the package substrate comprises:
electrically connecting the chip package to the package substrate through the second pads.

6. The method of claim 2, before the electrically connecting the plurality of second semiconductor chips to the plurality of first semiconductor chips, further comprising:
providing a second wafer including the plurality of second semiconductor chips;
forming second pads on a second surface of each of the second semiconductor chips;
attaching the second surface to a carrier wafer;
exposing the TSVs; and
forming first pads directly connected to the TSVs on a first surface of each of the second semiconductor chips.

7. The method of claim 6, wherein the exposing of the TSVs comprises:
exposing the TSVs while thinning the plurality of second semiconductor chips.

8. The method of claim 6, after the forming of the first pad, further comprising:
singulating the second semiconductor chips by sawing the second wafer.

9. The method of claim 1, after the electrically connecting the first semiconductor chips to the second semiconductor chips, further comprising:
forming an underfill layer between the first semiconductor chips and the second semiconductor chips.

10. A semiconductor package comprising:
a package substrate;
a first semiconductor chip having a first width;
a second semiconductor chip having a second width formed on the package substrate and including through silicon vias (TSVs), with the first semiconductor chip being disposed on the second semiconductor chip and the first width of the first semiconductor chip being greater than the second width of the second semiconductor chip;
a first molding layer surrounding the second semiconductor chip and formed under the first semiconductor chip without being formed on lateral surfaces of the first semiconductor chip, the first molding layer having a width that is smaller than or equal to the first width of the first semiconductor chip; and
a second molding layer formed on the package substrate and surrounding the first molding layer and the first semiconductor chip.

11. The semiconductor package of claim 10, wherein the second semiconductor chip includes first pads formed on a first surface and directly connected to the TSVs and second pads formed on a second surface, the first semiconductor chip includes third pads, wherein the first pads are electrically connected to the third pads.

12. The semiconductor package of claim 11, further comprising:
first bumps formed between the first pads and the third pads.

13. The semiconductor package of claim 12, further comprising:
an underfill layer formed between the first semiconductor chip and the second semiconductor chip.

14. The semiconductor device of claim 13, wherein the underfill layer surrounds the first bumps and is formed in the first molding layer.

15. The semiconductor device of claim 11, wherein the package substrate includes fourth pads, and further comprising second bumps electrically connecting the second pads to the fourth pads.

16. (canceled)

17. (canceled)
